(19) United States
(12) Patent Application Publication
(10) Pub. No.: US 2007/0089675 A1
(43) Pub. Date: Apr. 26, 2007

(54) Device for a coating process, a retort, and a process for internal coating

(75) Inventors: Thomas Beck, Panketal (DE); Thomas Berndt, Berlin (DE); Francis-Jurjen Ladru, Berlin (DE); Jean Muller, Berlin (DE); Michael Riemann, Berlin (DE)

Correspondence Address: SIEMENS CORPORATION;INTELLECTUAL PROPERTY DEPARTMENT, 170 WOOD AVENUE SOUTH, ISELIN, NJ, 08830, US

(73) Assignee: Siemens Aktiengesellschaft

(21) Appl. No.: 11/543,516

(22) Filed: Oct. 5, 2006

(30) Foreign Application Priority Data
Oct. 7, 2005 (EP) 05021896.5

(51) Int. Cl. C23C 16/00

(52) U.S. Cl. 118/722; 118/715

(57) ABSTRACT

In internal coating processes there is often the problem that an outer surface of the component to be coated is also coated. The device according to the invention consists in the fact that the outer surface is protected by a robust outer envelope and a filling material between the component to be coated and the outer envelope.

### CROSS REFERENCE TO RELATED APPLICATIONS

This application claims the benefits of European Patent application No. 05021896.5 filed Oct. 7, 2005. All of the applications are incorporated by reference herein in their entirety.

### FIELD OF THE INVENTION

The invention relates to a device for a process for coating a hollow body, a retort and a process for internal coating as claimed in the claims.

### BACKGROUND OF THE INVENTION

Hollow bodies, such as, for example, cast gas turbine blades, have cavities which are provided with an internal coating, in particular a metallic coating, for the purposes of protection against corrosion and/or oxidation. Coating processes available here are gas coating processes, such as, for example, the CVD or the PVD process. In this case, the metal for the coating is directed by means of a carrier gas into the cavity and condenses there on the inner surfaces of the hollow body. A metallic anticorrosion coating of between 30 μm and 100 μm, for example, then forms in the process. As a rule, the carrier gas is introduced through openings in the blade root of the turbine blade, flows through the cavity and discharges again through blade-specific discharge openings, e.g. at the trailing edge. The entire turbine blade is in this case located in a retort in which the pressure and temperature can be specifically set in relation to the process. After the carrier gas having the metal flows out from the discharge edge of the turbine blade, the metal also condenses in an undesirable manner on the outer surface of the turbine blade. After the removal of the turbine blade from the retort, these coating residues must be removed in a complicated manner by means of blasting or by another abrasive process. This takes a very long time and is very labor-intensive.

### SUMMARY OF THE INVENTION

The object of the invention is therefore to show a device and a retort with which coating of the outer surface can be prevented during an internal coating process on the components to be coated, and to show a process by means of which an outer coating is prevented during an internal coating process.

The object is achieved by a device, by a retort and by a process as claimed in the claims.

Further advantageous measures, which can be combined with one another in any desired advantageous manner, are listed in the subclaims.

### BRIEF DESCRIPTION OF THE DRAWINGS

In the drawing:

FIG. 1 shows a device according to the invention in cross section I-I,

FIG. 2 shows a perspective view of a device according to the invention,

FIG. 3 shows a cross section through a turbine blade,

FIG. 4 shows a perspective view of a turbine blade,

FIG. 5 shows a perspective view of a gas turbine.

### DETAILED DESCRIPTION OF THE INVENTION

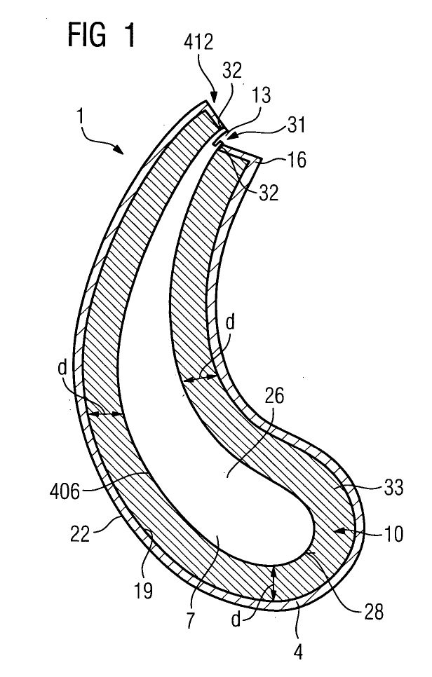

FIG. 1 shows the cross section through a device 1 according to the invention. The device 1 comprises a robust outer envelope 4 which has an inner surface 19 and an outer surface 22. Arranged in the outer envelope 4 is a hollow component 7, in particular a turbine blade 120, 130 (FIG. 3), for which the device 1 is described by way of example.

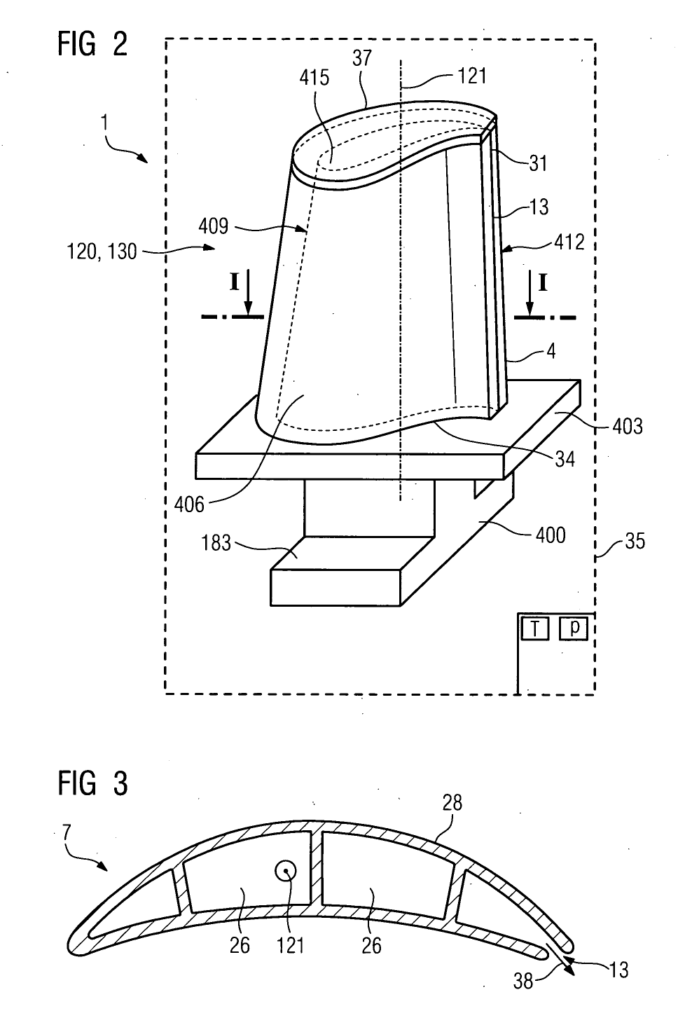

The turbine blade 120, 130 has a cavity 26, an outer surface 28 and at least one discharge opening 13, in particular a plurality of discharge openings 13, preferably along a trailing edge 412 (FIG. 2), from which a cooling medium flows out in an outflow direction 38 (FIG. 3) during operation of the turbine blade 120, 130. An elongated discharge opening 13 may likewise be present.

The outer envelope 4 is preferably adapted in its shape to the contour of an airfoil 406 of the turbine blade 120, 130, i.e. it looks like an airfoil of a turbine blade from the outside. In general, a rectangular shape could also always be used for the outer envelope 4, but this would mean that the distance d between the component 7 and the outer envelope 4 would then have to be filled with a relatively large amount of filling material 10.

In particular, the coating process is an aluminizing and/or chromizing process. Coating processes available here are gas coating processes, such as, for example, the CVD or PVD process. In this case, the metal, as a rule introduced through openings in the blade root 400 of the turbine blade 120, 130 by means of a carrier gas, is directed into the cavity 26 and condenses there on the inner surfaces of the turbine blade 120, 130, flows through the cavity 26 and discharges again through blade-specific discharge openings 13, e.g. at the trailing edge 412. A metallic anticorrosion coating of between 30 μm and 100 μm, for example, then forms in the process.

Likewise, a material used during the packing process can be introduced into the cavity 26, this material consisting of an inert filler and coating material (for example NaF+Al+ceramic or AIF+ceramic), which leads to the aluminum coating by heating.

Likewise, a slip or a paste can be introduced into the cavity 26, this slip or the paste being heated, so that a metallic vapor is produced which is deposited on the inner surfaces of the cavity 26.

There is no restriction at all with regard to the selection of the process for coating the cavity 26.

In FIG. 1, the outer envelope exhibits an envelope opening 31, through which the coating material can pass the outer envelope 4 after discharging from the discharge openings 13 of the component 120, 130.

Between the outer surface 28 of the turbine blade 120, 130 and the inner surface 19 of the preferably fixed outer envelope 4, there is a distance d which is large enough in order to fill this interior space 33 between outer envelope 4 and turbine blade 7 with a filling material 10. Preferably the distance d=5-20 mm. The shortest distance d between the blade surface 28 and the inner surface 19 of the outer envelope need not be uniform, but must always be so large that a filling material 10 can be introduced.

The filling material 10 used is preferably fine Al₂O₃ powder. The filling material in this case is selected in such a way that it is chemically inert at the coating temperature and thus can easily be reused. Of course, there may be spacers in the interior space 33 which ensure a minimum distance.

The outer envelope 4 is therefore widened by at least 2×d relative to the turbine blade 120, 130.

Since the turbine blade 120, 130 tapers to a point at the trailing edge 412, the outer envelope 4 has a width 2×d there. However, the outer envelope 4 does not taper to a point like the turbine blade 120, 130, but rather has a bent region 16 which bears at its end at the region 32 against the blade 120, 130. It is thus ensured that there is a sufficiently large distance d between airfoil 406 and outer envelope 4 even in the region 32 of the trailing edge 412. In principle, however, it is also possible for the outer envelope 4 to likewise be tapered to a point at its end.

In the region 32 of the trailing edge 412, the outer envelope 4 is adapted in such a way that it bears against the turbine blade 120, 130 only in this region 32, so that only the discharge openings 13 in the region of the trailing edge 412 are exposed. The discharge openings 13 are arranged along a line (trailing edge 412), so that the envelope opening 31 is accordingly preferably of elongated design.

The outer envelope 4 is conceived in such a way that it can be used for various turbine blades 120, 130 which may have various lengths and various curvatures, that is to say, for example, for turbine blades 120, 130 of various blade stages. A standardized outer envelope 4 can therefore be used for various turbine blades 120, 130, since the distances d can be evened out in a variable manner with the filling material 10.

FIG. 2 shows the device 1 according to the invention in a three-dimensional illustration. The outer envelope 4 completely encloses the airfoil of the turbine blade 120, 130 and rests, for example, on the platform 403. If need be, the outer envelope 4 is sealed off at the surfaces 34 in contact with the blade platform 403. The contact surfaces in the region 32 of the envelope opening 31 between the outer envelope 4 and the turbine blade 7 may likewise be sealed off.

The seal is not necessary as a rule, since the filling material 10 prevents penetration of material between outer envelope 4 and turbine blade 120, 130 and thus protects the airfoil 406 from a coating. If need be, a seal may be used in order to prevent filling material 10 from running out of the outer envelope 4.

The outer envelope 4 may have, for example, a lid 37, through which the interior space 33 between the airfoil and the outer envelope 4 is filled with the filling material. After that, the lid 37 can be closed again or brazed up.

Other ways of introducing the filling material 10 are likewise conceivable. It is therefore just as possible not to use a lid 37, but rather to fill the interior space 33 between airfoil 406 and outer envelope 4 and likewise cover a blade tip 415 with filling material 10, since the outer envelope 4 only has the task of holding the filling material 10 together.

The device 1 according to the invention is preferably arranged in a retort 35, which is indicated in FIG. 2 by broken lines.

The temperature T and/or the pressure p can be set and monitored in a controlled manner inside the retort 35, the temperature T and the pressure p also being present at the component 7, 120, 130, so that the coating process can be carried out in a controlled manner in the turbine blade 120, 130. The retort 35 may have a pump which sucks up the coating material discharging from the outer envelope 4.

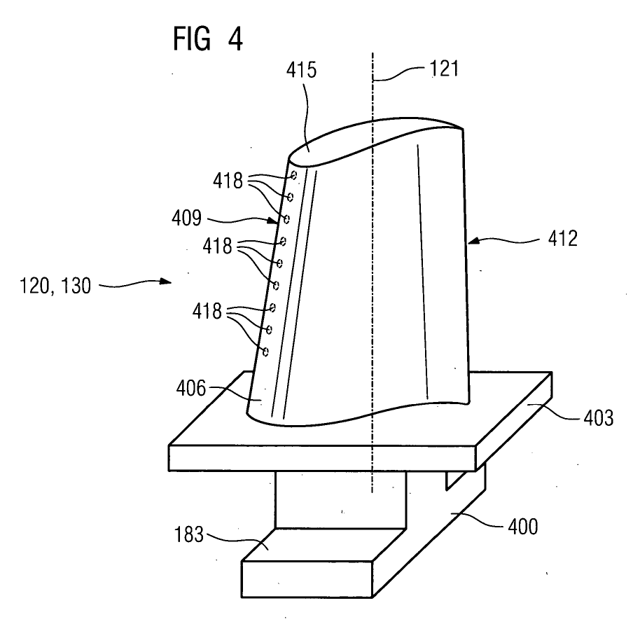

FIG. 4, in a perspective view, shows a moving blade 120 or guide blade 130 of a turbomachine, said moving blade or guide blade extending along a longitudinal axis 121.

The turbomachine may be a gas turbine of an aircraft or of a power plant for the generation of electricity, a steam turbine or a compressor.

The blade 120, 130 has, following one another along the longitudinal axis 121, a fastening region 400, an adjoining blade platform 403 and an airfoil 406. As a guide blade 130, the blade 130 may have a further platform (not shown) at its blade tip 415.

Formed in the fastening region 400 is a blade root 183, which serves to fasten the moving blades 120 to a shaft or a disk. The blade root 183 is configured, for example, as a hammer head. Other configurations as a fir-tree or dovetail root are possible.

For a medium which flows past the airfoil 406, the blade 120, 130 has a leading edge 409 and a trailing edge 412.

In the case of conventional blades 120, 130, solid metallic materials, in particular superalloys, are used in all regions 400, 403, 406 of the blade 120, 130.

Such superalloys are known, for example, from EP 1 204 776 B1, EP 1 306 454, EP 1 319 729 A1, WO 99/67435 or WO 00/44949; these publications are part of the disclosure with regard to the chemical composition of the alloy. In this case, the blade 120, 130 may be produced by a casting process, including by means of directional solidification, by a forging process, by a milling process or by combinations thereof.

Workpieces having a single-crystalline structure or structures are used as components for machines which are subjected to high mechanical, thermal and/or chemical loads during operation.

Such single-crystalline workpieces are produced, for example, by directional solidification from the melt. This involves casting processes in which the liquid metallic alloy is solidified to form the single-crystalline structure, i.e. to form the single-crystalline workpiece, or is directionally solidified.

In this case, dendritic crystals are oriented along the heat flow and form either a columnar-crystalline grain structure (columnar, i.e. the grains run over the entire length of the workpiece and are referred to here, according to general usage, as directionally solidified) or a single-crystalline structure, i.e. the entire workpiece consists of a single crystal. In this process, the transition to the globulitic (polycrystalline) solidification must be avoided, since nondirectional growth causes transversal and longitudinal grain boundaries to form, which destroy the good properties of the directionally solidified or single-crystalline component.

The structures in question are generally directionally solidified structures, which thus means both single crystals, which have no grain limits or at most small-angle grain limits, and columnar-crystal structures, which certainly have grain limits running in the longitudinal direction, but no transversal grain limits. These second-mentioned structures are also referred to as directionally solidified structures.

Such processes are known from U.S. Pat. No. 6,024,792 and EP 0 892 090 A1; these publications are part of the disclosure.

Likewise, the blades 120, 130 may have anticorrosion and antioxidation coatings (e.g. MCrAlX; where M is at least one element of the group iron (Fe), cobalt (Co), Nickel (Ni), X is an active element and stands for yttrium (Y) and/or silicon and/or at least one element of the rare earths, or hafnium (Hf). Such alloys are known from EP 0 486 489 B1, EP 0 786 017 B1, EP 0 412 397 B1 or EP 1 306 454 A1, which are to be part of this disclosure with regard to the chemical composition of the alloy. The process according to the invention is used for an internal coating.

On the MCrAlX coating, there may also be a heat-insulating layer, which consists, for example, of ZrO₂, Y₂O₃—ZrO₂, i.e. it is not partly or completely stabilized by yttrium oxide and/or calcium oxide and/or magnesium oxide.

Columnar grains are produced in the heat-insulating layer by suitable coating processes, such as, for example, electron beam physical vapor deposition (EB-PVD), or porous grains affected by micro or macro cracks are produced in the heat-insulating layer by, for example, atmospheric plasma spraying (APS).

Refurbishment means that components 120, 130 may possibly have to be freed of protective coatings after their use (e.g. by sand blasting). After that, the corrosion and/or oxidation layers or products are removed. If need be, cracks in the component 120, 130 are also repaired. The component 120, 130 is then recoated and used again.

The blade 120, 130 may be of hollow or solid design. If the blade 120, 130 is to be cooled, it is hollow and possibly also has film-cooling holes 418 (indicated by broken lines).

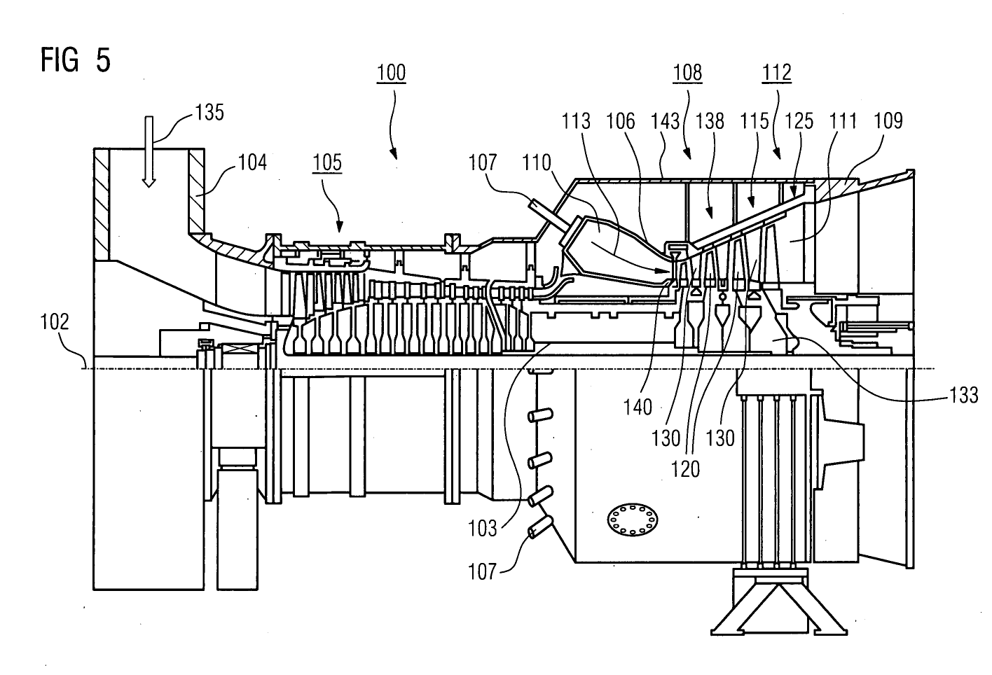

FIG. 5 shows by way of example a gas turbine 100 in a longitudinal partial section. In the interior, the gas turbine 100 has a rotor 103 which is rotatably mounted about a rotation axis 102 and has a shaft 101 and is also referred to as turbine rotor.

Following one another along the rotor 103 are an intake casing 104, a compressor 105, a, for example torus-like, annular combustion chamber 110, in particular an annular combustion chamber, having a plurality of coaxially arranged burners 107, a turbine 108 and the exhaust-gas casing 109.

The annular combustion chamber 110 communicates with a, for example annular, hot-gas duct 111. There, for example four turbine stages 112 connected one behind the other form the turbine 108.

Each turbine stage 112 is formed, for example, from two blade rings. As viewed in the direction of flow of a working medium 113, a row 125 formed from moving blades 120 follows a guide-blade row 115 in the hot-gas duct 111.

The guide blades 130 are in this case fastened to an inner casing 138 of a stator 143, whereas the moving blades 120 of a row 125 are attached to the rotor 103, for example by means of a turbine disk 133. Coupled to the rotor 103 is a generator or a driven machine (not shown).

During operation of the gas turbine 100, air 135 is drawn in by the compressor 105 through the intake casing 104 and is compressed. The air provided at the turbine-side end of the compressor 105 is directed to the burners 107 and is mixed there with a fuel. The mixture is then burned, with a working medium 113 being formed in the combustion chamber 110. The working medium 113 flows from there along the hot-gas duct 111 past the guide blades 130 and the moving blades 120. At the moving blades 120, the working medium 113 expands in an impulse-transmitting manner, so that the moving blades 120 drive the rotor 103 and the latter drives the driven machine coupled to it.

The components exposed to the hot working medium 113 are subjected to thermal loads during the operation of the gas turbine 100. Apart from the heat shield elements lining the annular combustion chamber 110, the guide blades 130 and moving blades 120 of the first turbine stage 112 as viewed in the flow direction of the working medium 113 are subjected to the highest thermal loading.

In order to withstand the temperatures prevailing there, said blades can be cooled by means of a coolant.

Likewise, substrates of the components may have a directional structure, i.e. they are single-crystalline (SX structure) or have only longitudinally directed grains (DS structure).

The materials used for the components, in particular for the turbine blades 120, 130 and components of the combustion chamber 110, are, for example, iron-, nickel- or cobalt-based superalloys.

Such superalloys are known, for example, from EP 1 204 776 B1, EP 1 306 454, EP 1 319 729 A1, WO 99/67435 or WO 00/44949; these publications are part of the disclosure with regard to the chemical composition of the alloys.

The guide blade 130 has a guide-blade root (not shown here) facing the internal casing 138 of the turbine 108 and a guide-blade tip opposite the guide-blade root. The guide-blade tip faces the rotor 103 and is fixed to a fastening ring 140 of the stator 143.

1-8. (canceled)

9. A device to assist coating a cavity of a hollow component, comprising:
an outer envelope configured to receive the hollow component, and a filling material, the outer envelope configured to maintain a gap of uniform distance from an inner surface of the outer envelope and an outer surface of the hollow component; and
an opening arranged partly in a region of a discharge opening of the hollow component where the coating material can discharge during the coating process.

10. The device as claimed in claim 9, wherein the outer envelope is configured to the outer contour of the component.

11. The device as claimed in claim 10, wherein the hollow component is a turbine blade.

12. The device as claimed in claim 11, wherein the envelope opening is elongated.

13. A retort, comprising:
a bottom portion;
a first wall arranged perpendicular to the bottom portion;
a second wall adjacent to the first wall and perpendicular to the bottom wall;
a third wall arranged opposite the first wall and adjacent to the second wall and perpendicular to the bottom portion;
a fourth wall arranged opposite the second wall and adjacent to the first and third walls and perpendicular to the bottom portion;
a top portion spanning the first, second, third and fourth walls to form a closed box like interior portion;
a pressure setting device connected to the interior portion;
a temperature setting device connected to the interior portion; and
a monitoring device that monitors the pressure and temperature of the interior portion,
wherein the retort is configured to:
receive a hollow turbine component in the interior portion, and
set the temperature and pressure within the interior portion with the turbine component present with in the retort.

14. The retort as claimed in claim 13, wherein a pump is connected to the interior portion.

15. The retort as claimed in claim 14, wherein the turbine component is a turbine blade or vane.

16. The retort as claimed in claim 15, wherein the retort is further configured to perform a coating process of the turbine component arranged in the interior portion.

17. A process for the internal coating of a hollow turbine component having a cavity, comprising:
inserting the hollow turbine component into an outer envelope:
surrounding the hollow turbine component at a predetermined distance between an inner surface of the outer envelope and an inner surface of the hollow turbine component;
providing an opening that coincides with a region of a discharge opening of the hollow turbine component;
filling the predetermined distance between the outer envelope and the component with a filling material;
introducing coating material into the cavity of the hollow turbine component; and
discharging a portion of the coating material from the cavity and the hollow turbine component through the discharge opening.

18. The process as claimed in claim 17, further comprising an aluminizing process is performed on the hollow turbine component.

19. The process as claimed in claim 18, wherein the filling material is chemically inert at the coating temperature.

20. The process as claimed in claim 19, wherein the hollow turbine component is a turbine blade or vane.
